(19) United States
(12) Patent Application Publication
(10) Pub. No.: US 2019/0260354 A1
(43) Pub. Date: Aug. 22, 2019

(54) SELF-SUPPORTING CAVITY STRUCTURE OF A BULK ACOUSTIC RESONATOR AND METHOD THEREFOR

(71) Applicant: OEpic SEMICONDUCTORS, INC, SUNNYVALE, CA (US)

(72) Inventors: YI-CHING PAO, SUNNYVALE, CA (US); MAJID RIAZIAT, SUNNYVALE, CA (US); JAMES PAO, SUNNYVALE, CA (US)

(21) Appl. No.: 16/281,368

(22) Filed: Feb. 21, 2019

Related U.S. Application Data
(60) Provisional application No. 62/633,754, filed on Feb. 22, 2018.

(51) Int. Cl. H03H 9/17; H03H 9/02

(52) U.S. Cl. CPC H03H 9/173; H03H 9/02047; H03H 9/02015; H03H 9/02086

(57) ABSTRACT

A Bulk Acoustic Resonator (BAR) structure has a substrate. A cavity pattern is formed on the substrate. A Bulk Acoustic Wave (BAW) structure is formed on the cavity pattern and the substrate, wherein portions of the cavity pattern are exposed. The cavity pattern under the BAW structure is removed creating a self-sustaining cavity to form the novel cavity structure.

### RELATED APPLICATIONS

This patent application is related to U.S. Provisional Application No. 62/633,754 filed Feb. 22, 2018, entitled “NOVEL SELF-SUPPORTING CAVITY STRUCTURE OF BULK ACOUSTIC RESONATOR” in the names of Yi-Ching Pao, Majid Riaziat and James Pao, and which is incorporated herein by reference in its entirety. The present patent application claims the benefit under 35 U.S.C § 119(e).

### TECHNICAL FIELD

The present invention generally relates to Bulk Acoustic Wave (BAW) structures and, more particularly to, a cavity formation and manufacturing process that simplifies the cavity formation underneath the BAW structure, and eliminates the need of substrate trench etching and subsequent planarization processes.

### BACKGROUND

Piezoelectric thin film Bulk Acoustic Wave (BAW) structures are typically used to manufacture Bulk Acoustic Resonators (BAR) for filter and duplexer in microwave applications. Two basic BAW structures have developed over the years, namely FBAR (Film BAR) and SMBAR. (Solidly Mounted BAR) FBAR and SMBAR both have their own pros and cons, but overall the FBAR has been gaining more and more market share in today's microwave communication applications. The FBAR structurer is a cavity-based structure wherein the manufacturing of it has been mainly based on etching a trench on the silicon substrate, combined with surface planarization with Chemical Mechanical Polishing (CMP).

U.S. Pat. No. 6,060,818 discloses a prior art method of forming a FBAR structure. In this patent, as may be seen in FIGS. 1A-1E, the FBAR structure may be formed by etching a cavity 10 into a silicon substrate 12 as shown in FIG. 1A. A thin layer of thermal oxide 14 may be applied to prevent chemical diffusion. Such diffusion may convert the silicon to a conductor, which would interfere with the electrical operation of the final device. A layer of phosphor-silica-glass (PSG) 16 may be deposited filling the cavity 10 as shown in FIG. 1B. The surface of the PSG layer 16 is first planar zed by polishing with a slurry to remove the portion of the PSG layer 16 outside of the cavity 10 as shown in FIG. 1C. The remaining PSG layer 16 can then be polished using a more refined slurry. As shown in FIG. 1D, an FBAR 20 may then be formed. A bottom electrode 18 of the FBAR 20 may then he deposited. After the bottom electrode 18 has been deposited, a piezoelectric layer 22 of the FBAR 20 may be deposited. Finally, the top electrode 24 may deposited. As shown in FIG. 1E, the PSG layer 16 in the cavity 10 may be removed through via holes to form the underlying cavity 10. The above, process is time consuming and complicated due to the multiple layers than need to be formed.

Therefore, it would be desirable to provide a device and method that overcome the above problems. The device and method would simplify the cavity formation underneath the BAW structure, and eliminate the need of substrate trench etching and subsequent planarization processes.

### SUMMARY

In accordance with one embodiment, a Bulk Acoustic Resonator (BAR) structure is disclosed, The Bulk Acoustic Resonator (BAR) structure has a substrate. A cavity pattern is formed on the substrate, A Bulk Acoustic Wave (BAW) structure is formed on the cavity pattern and the substrate, wherein portions of the cavity pattern are exposed. The cavity pattern under the BAW structure is removed creating a cavity.

In accordance with one embodiment, a method of forming method of forming a Bulk Acoustic Resonator (BAR) structure is disclosed. The method comprising: providing a substrate; applying an interfacial layer on the substrate; etching the interfacial layer to form a cavity pattern; forming a Bulk Acoustic Wave (BAW) structure on the cavity pattern and the substrate, wherein portions of the cavity pattern are exposed; and removing the cavity pattern under the BAW structure to create a cavity.

### BRIEF DESCRIPTION OF THE DRAWINGS

The present application is further detailed with respect to the following drawings. These figures are not intended to limit the scope of the present application but rather illustrate certain attributes thereof. The same reference numbers will be used throughout the drawings to refer to the same or like parts.

FIG. 1A-1E show cross-sectional views of a method for forming a prior art Bulk Acoustic Wave (BAW) device;

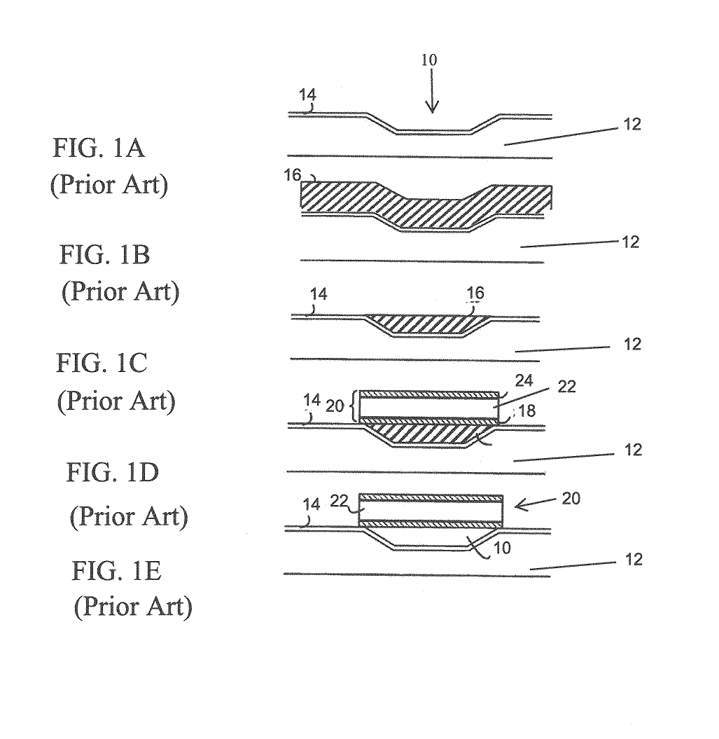

FIG. 2A-2E show cross-sectional views of an exemplary processing sequence of forming a self-sustaining FBAR device in, accordance with on aspect of the present application;

FIG. 3 shows a cross-sectional view of an exemplary BAW structure consisting of two Molybdenum (Mo) metal layers sandwiching a piezo-electric Aluminum Nitride (AlN) layer in accordance with one aspect of the present application; and

FIG. 4A-4B show a cross-sectional view and corresponding top-down view of an exemplary self-sustaining FBAR structure in accordance with one aspect of the present application.

### DESCRIPTION OF THE APPLICATION

The description set forth below in connection with the appended drawings is intended as a description of presently preferred embodiments of the disclosure and is not intended to represent the only forms in which the, present disclosure may be constructed and/or utilized. The description sets forth the functions and the sequence of steps for constructing and operating the disclosure in connection with the illustrated embodiments. it is to be understood, however, that the same or equivalent functions and sequences may be accomplished, by different embodiments that are also intended to be encompassed within the spirit and scope of this disclosure.

The current invention involves a novel cavity formation and manufacturing process that simplifies a cavity formation underneath a BAW structure, and eliminates the need of substrate trench etching and subsequent planarization processes. The new cavity forming process uses a bare thermal oxide and BAW (typically sandwiched Mo—AlN—Mo) layer itself to form a cavity without any substrate trench etching and silica glass filling and planarization processes as in the prior art.

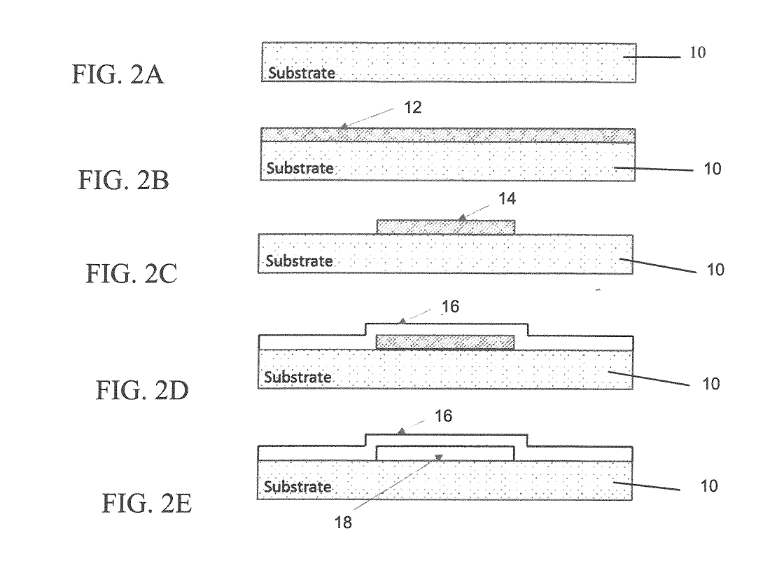

Referring to FIGS. 2A-2E, a process of forming a FBAR may be seen. A substrate 10 may be provided. The substrate 10 maybe a conventional silicon wafer of the type utilized in integrated circuit fabrication. An interfacial layer 12 may be applied to the substrate 10. The interfacial layer can be a spin on dielectric typically used in semiconductor processing such as Polyimide, Benzocyclobutene (BCB), silica glass, thermal oxide, and e-beam evaporated or PECVD deposited SiOx (silicon oxide) or SiNx (silicon nitride). The above are given as examples and should not be seen in a limiting manner. The interfacial layer may be several tenth of a micron (such as thermal oxide) to several microns (such as spin on glass) in thickness.

In accordance with one embodiment, thermal oxide may be used. Thermal oxide may be used due to two factors. One is that a thickness of the cavity to be formed is in the range of couple thousand angstroms to maybe a half micron which is readily achievable by using thermal oxide. The other factor is that thermal oxide is relatively “thin and smooth” in nature compared to other interfacial layers coated either by spin on and bake or physical evaporated or chemically deposited.

Once the interfacial layer 12 may be applied, a cavity pattern 14 may be formed. The cavity pattern 14 may be formed by removing portions of the interfacial layer 12 to form a shape of a cavity 18 to be formed. The cavity pattern 14 may generally be rectangular in shape with dimensions in the range of one to couple hundred microns in size. The cavity thickness is normally determined by the resonant frequency, the higher the frequency the thinner the thickness can be. For a resonant frequency of 2 GHz, the minimum cavity thickness may be in the range of 0.5 um to avoid the acoustic energy to tunnel through the cavity.

The cavity pattern 14 may be created by standard photolithography and the interfacial layer 12 may be etched, as shown in FIG. 2G. If the interfacial layer 12 is a thermal oxide, a selective etchant of HF (Hydrofluoric acid) may be used which is sufficiently stable against common photoresist and has a SiOx etch rate of 2-3 nm/min making it suitable for the application as described.

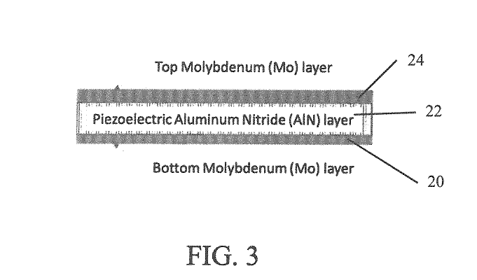

After the cavity pattern 14 may be formed, a BAW structure 16 may be formed. The BAA structure 16 may be formed of a plurality of layers as shown in FIG. 3. As may be seen in FIG. 3, the BAW structure 16 may be comprised of a bottom metal layer 20. A piezoelectric layer 22 may then be formed on, the bottom metal layer 20. A top metal layer 24 may then be applied on the piezoelectric layer 22. In accordance with one embodiment, the bottom metal layer 20 may consists of Molybdenum (Mo), the piezoelectric layer 22 may be Aluminum Nitride (AlN) and the top metal layer 26 may be Molybdenum (Mo). The BAW structure 16 may be formed by having the metal layers (i.e., Mo—AlN—Mo) “blanket” deposited by a sputtering process. The sputtering process may be used to provide the sidewall coverage as shown in FIG. 2D,

In accordance with one embodiment, the bottom metal layer 20 may consists of Molybdenum (Mo) in a thickness of around one to several thousand angstroms. The piezoelectric layer 22 may be Aluminum Nitride (AlN) having a thickness of a couple of microns depending on the resonant frequency. The top metal layer 26 may be Molybdenum (Mo) having, a thickness of several thousand angstroms to may be a couple of microns as the top metal layer 26 thickness may he used for frequency tuning as an example.

Since mechanically the piezoelectric layer 22 is relatively rigid and strong, it is feasible to use it to form the cavity 18 by itself without introducing any additional post like mechanical supports or complicated cross-sectional structures as used in the prior art.

As may be seen in FIG. 2E, after the BAW structure 16 may be formed, the cavity pattern 14 formed of the remaining interfacial layer 12 may he removed. By removing the remaining interfacial layer 12 under the BAW structure 16, the cavity 18 may be formed. In accordance with one embodiment, the cavity pattern 14 may be chemically removed. In accordance with one embodiment, for thermal oxide a selective etchant of HF (Hydrofluoric acid) may be used which is sufficiently stable against common photoresist and has a SiOx etch rate of 2-3 um/min making it suitable for the application as described.

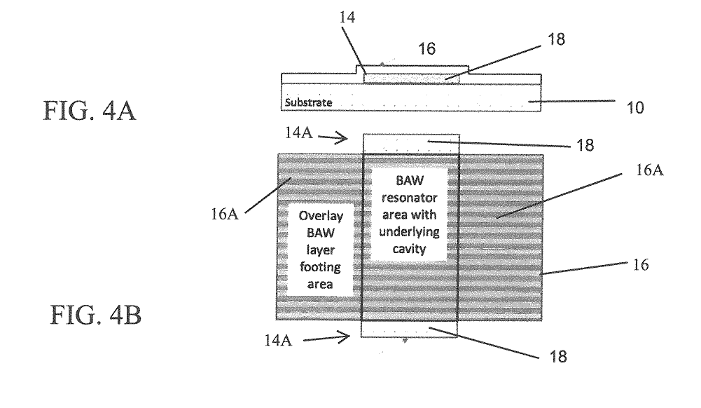

Referring now to FIG. 4A-4B, a cross-sectional view and corresponding top-down view of an FBAR structure formed in accordance with the above method may be seen. The shape of the cavity pattern 14 is typically rectangle and the BAW structure 16 may have enough overlay area to form a “footing” area to provide the mechanical support. In other words, the BAW structure 16 has an overlay area 16A that extends past the cavity 18 to provide support for keeping BAW structure 16 above the cavity 18 without introducing any additional post like mechanical supports or complicated cross-sectional structures as used in the prior art.

The BAW resonator region created by the cavity pattern 14 has a dimension of typically tens to couple hundred microns. As may be seen in FIG. 4B, a portion 14A of the cavity pattern 14 remains exposed from the BAW structure 16. The exposed portion 14A of the cavity pattern 14 may provide an area to chemically etch and remove the remaining interfacial layer 12 forming the cavity pattern 14. In accordance with one embodiment, a pair of opposing ends 14A of the cavity pattern 14 may extend past the BAW structure 16. Since the opposing ends 14A of the cavity pattern 14 extend past the BAW structure 16, the opposing ends 14A may provide etch channels to chemically etch and remove the remaining interfacial layer 12 forming the cavity pattern 14.

While embodiments of the disclosure have been described in terms of various specific embodiments, those skilled in the art will recognize that the embodiments of the disclosure may be practiced with modifications within the spirit and scope of the claims

What is claimed is:

1. A Bulk Acoustic Resonator (BAR) structure comprising:
a substrate;
a cavity pattern formed on the substrate; and
a Bulk Acoustic Wave (BAW) structure formed on the cavity pattern and the substrate, wherein portions of the cavity pattern are exposed;
wherein the cavity pattern under the RAW structure is removed creating a cavity.

2. The BAR structure of claim 1, wherein the cavity pattern comprises an interfacial layer formed on the substrate, wherein the interfacial layer is etched forming the cavity pattern.

3. The BAR structure of claim 2, wherein the interfacial layer is a dielectric material.

4. The BAR structure of claim 2, wherein the interfacial layer comprises one of: Polyimide, Benzocyclobutene (BCB), silica glass, thermal oxide, SiOx (silicon oxide) or SiNx (silicon nitride).

5. The BAR structure of claim 1, wherein the BAW structure comprises:
a bottom Molybdenum (Mo) layer formed on the cavity pattern and the substrate;
a piezoelectric Aluminum Nitride (AlN) layer applied on the bottom Mo layer; and
a top Molybdenum (Mo) layer applied to the piezoelectric AlN layer.

6. The BAR structure of claim 2, wherein the interfacial layer has a thickness of 0.1 to 2 microns.

7. The BAR structure of claim 2, wherein the cavity pattern extends beyond the BAW structure on at least one side.

8. The BAR structure of claim 2, wherein the cavity pattern extends beyond the BAW structure on a pair of opposing sides.

9. A method of funning a Bulk Acoustic Resonator (BAR) structure comprising:
providing a substrate;
applying an interfacial layer on, the substrate;
etching the interfacial layer to form a cavity pattern;
forming a Bulk Acoustic Wave (BAW) structure on the cavity pattern and the substrate, wherein portions of the cavity pattern are exposed; and
removing the cavity pattern under the BAW structure to create a cavity.

10. The method of claim 9, wherein the interfacial layer is a dielectric material.

11. The method of claim 9, wherein the interfacial layer comprises one of: Polyimide, Benzocyclobutene (BCB), silica glass, thermal oxide, SiOx (silicon oxide) or SiNx (silicon nitride).

12. The method of claim 9, wherein applying the interfacial layer comprises applying the interfacial layer having a thickness of 0.1 to 2 microns.

13. The method of claim 9, wherein applying the interfacial layer comprises applying a thermal oxide as the interfacial layer having a thickness of 0.1 to 2 microns.

14. The method of claim 9, wherein storming the BAW structure comprises:
applying a bottom Molybdenum (Mo) layer on the cavity pattern and the substrate;
applying a piezoelectric Aluminum Nitride (AlN) layer on the bottom Mo layer; and
applying a top Molybdenum (Mo) layer to the piezoelectric AlN layer;
wherein portions of the cavity pattern remained exposed.

15. The method of claim 14, comprises sputtering the bottom Mo layer, the piezoelectric AlN layer and the top Mo layer to provide sidewall coverage while portions of the cavity pattern remained exposed.

16. The method of claim 14, wherein the cavity pattern extends beyond the BAW structure on at least one side.

17. The method of claim 14, wherein the cavity pattern extends beyond the BAW structure on a pair of opposing sides.

18. The method of claim 9, wherein removing the cavity pattern under the BAW structure comprises chemically etching the interfacial layer forming the cavity pattern.

19. The method of claim 18, comprising using Hydrofluoric acid (HF) as an etchant to chemically etch the interfacial layer forming the cavity pattern.
